(19) United States
(12) Patent Application Publication
(10) Pub. No.: US 2017/0070240 A1
(43) Pub. Date: Mar. 9, 2017

(54) MEMORY SYSTEM INCLUDING ERROR CORRECTOR AND OPERATING METHOD THEREOF

(71) Applicant: SK hynix Inc., Icheon-si (KR)

(72) Inventor: Nack Hyun KIM, Suwon-si (KR)

(21) Appl. No.: 15/005,237

(22) Filed: Jan. 25, 2016

(30) Foreign Application Priority Data
Sep. 3, 2015 (KR) 10-2015-0125052

(51) Int. Cl. H03M 13/27; H03M 13/11; H03M 13/00

(52) U.S. Cl. CPC H03M 13/2707; H03M 13/6566; H03M 13/1108; H03M 13/1111; H03M 13/1177

(57) ABSTRACT

A memory system includes a controller and a semiconductor memory device. The semiconductor memory device stores a data set having main data bits and parity bits and provide soft decision bit streams corresponding to the data set in response to control signals of the controller. The controller includes a soft decision decoder for identifying data set by decoding the soft decision bit streams according to a first decoding method, a deinterleaver for deinterleaving the identified data set, a hard decision decoder for decoding the deinterleaved data set according to a second decoding method based on parity bits included in the deinterleaved data set, and outputting a failed data set if the decoding according to the second decoding method has failed, and an interleaver for interleaving the failed data set. The interleaved data set is fed back to the soft decision decoder.

### CROSS-REFERENCE TO RELATED APPLICATION

The present application claims priority to Korean patent application number 10-2015-0125052 filed on Sep. 3, 2015, in the Korean Intellectual Property Office, the entire disclosure of which is incorporated by reference herein.

### BACKGROUND

1. Field

An aspect of the present disclosure generally relates to an electronic device, and more particularly to a memory system including an error corrector and an operating method thereof.

2. Description of the Related Art

A semiconductor memory device is a data storage device implemented on a semiconductor integrated circuit. The semiconductor memory device is generally classified into a volatile memory device and a nonvolatile memory device.

The volatile memory is a memory device that loses stored data when a power supply is cut off. Examples of the volatile memory include a static random access memory (SRAM), a dynamic RAM (DRAM), a synchronous DRAM (SDRAM), and the like. The nonvolatile memory is a memory device that retains stored data even when a power supply is cut off. Examples of the nonvolatile memory include a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), and the like. The flash memory is generally classified into a NOR type flash memory and a NAND type flash memory.

### SUMMARY

Embodiments provide a memory system having an improved error correction performance and an operating method thereof.

According to an aspect of the present disclosure, there is provided a memory system including: a controller; and a semiconductor memory device configured to store a data set having main data bits and parity bits and provide soft decision bit streams corresponding to the data set in response to control of the controller, wherein the controller includes: a soft decision decoder configured to sense the data set by decoding the soft decision bit streams according to a first decoding method; a deinterleaver configured to deinterleave the sensed data set; a hard decision decoder configured to decode the deinterleaved data set according to a second decoding method with reference to the parity bits included in the deinterleaved data set, and output a failed data set when the decoding corresponding to the second decoding method fails; and an interleaver configured to interleave the failed data set, wherein the interleaved data set is fed back to the soft decision decoder.

The soft decision decoder may re-decode the soft decision bit streams with reference to the interleaved data set.

The soft decision decoder, the deinterleaver, the hard decision decoder, and the interleaver may be included in one feedback loop.

The failed data set may have the same size as the data set.

The main data bits may be acquired when the decoding corresponding to the second decoding method passes. The hard decision decoder may output the main data bits as host data.

The deinterleaved data set may be divided into a plurality of data blocks. The decoding corresponding to the second decoding method may be performed in units of data blocks. The failed data set may include a data block of which the decoding corresponding to the second decoding method fails and a data block of which the decoding corresponding to the second decoding method passes.

The hard decision decoder may further output a plurality of flag information respectively corresponding to the plurality of data blocks. Each of the plurality of flag information may represent whether the decoding corresponding to the second decoding method has passed or failed with respect to a corresponding data block.

The soft decision decoder may re-decode the soft decision bit streams with reference to the plurality of flag information and the interleaved data set.

The semiconductor memory device may perform read retry in response to control of the controller, to output, to the controller, second soft decision bit streams corresponding to the data set. The read retry may be performed in parallel to at least one of the decoding corresponding to the first decoding method, the deinterleaving, the decoding corresponding to the second decoding method, and the interleaving.

The soft decision decoder may decode the second soft decision bit streams according to the first decoding method with reference to the interleaved data set.

When the decoding corresponding to the second decoding method passes, the controller may discard the second soft decision bit streams.

The first decoding method may correspond to a convolution code.

The first decoding method may correspond to a low density parity check (LDPC) code.

The second decoding method may correspond to a Reed Solomon code.

The second decoding method may correspond to a Bose, Chaudhuri, and Hocquenghem (BCH) code.

The controller may include a hard decision encoder configured to generate the parity bits by encoding host data according to a second encoding method corresponding to the second decoding method; and a second interleaver configured to generate the data set by interleaving the host data and the parity bits. The data set may be encoded according to a first encoding method corresponding to the first decoding method to be stored in the semiconductor memory device.

According to another aspect of the present disclosure, there is provided a method of operating a semiconductor device, the method including: providing soft decision bit streams corresponding to a data set, wherein the data set has main data bits and parity bits; sensing the data set by decoding the soft decision bit streams according to a first decoding method; deinterleaving the sensed data set; decoding the deinterleaved data set according to a second decoding method with reference to the parity bits of the deinterleaved data set; when the decoding corresponding to the second decoding method fails, outputs a failed data set; interleaving the failed data set; and re-performing the decoding corresponding to the first decoding method with reference to the deinterleaved data set.

The deinterleaving of the sensed data set, the decoding corresponding to the second decoding method, the outputting of the failed data set, the interleaving of the failed data set, and the re-performing of the decoding corresponding to the first decoding method may be repeated until the decoding corresponding to the second decoding method passes.

The failed data set may have the same size as the data set.

The method may further include providing second soft decision bit streams corresponding to the data set. The providing of the second soft decision bit streams may be performed in parallel to at least one of the decoding corresponding to the first decoding method, the deinterleaving of the sensed data set, the decoding corresponding to the second decoding method, the outputting of the failed data set, and the interleaving of the failed data set.

The re-performing of the decoding corresponding to the first decoding method may include decoding the second soft decision bit streams according to the first decoding method with reference to the interleaved data set.

According to the present disclosure, it is possible to a memory system having improved error correction performance and an operating method thereof.

### BRIEF DESCRIPTION OF THE DRAWINGS

In the drawing figures, dimensions may be exaggerated for clarity of illustration. The accompanying figures, in which like reference numerals refer to identical or functionally similar elements throughout the separate views and which together with the detailed description below are incorporated in and form part of the specification, serve to further illustrate various embodiments and explain various principles and advantages all in accordance with the present invention.

FIG. 1 is a block diagram illustrating a memory system according to an embodiment of the present disclosure.

FIG. 2 is a block diagram illustrating an error corrector of FIG. 1.

FIG. 3 is a block diagram illustrating an encoding unit of FIG. 2.

FIG. 4 is a conceptual diagram illustrating a process of encoding host data.

FIG. 5 is a block diagram illustrating a decoding unit of FIG. 2.

FIG. 6 is a flowchart illustrating a decoding method according to an embodiment of the present disclosure.

FIG. 7 is a diagram conceptually illustrating data processed according to a decoding method in accordance with an embodiment.

FIG. 8 is a conceptual diagram illustrating a deinterleaved data set and a failed data set.

FIG. 9 is a conceptual diagram illustrating flag information.

FIG. 10 is a flowcharting illustrating a method of operating the memory system according to an embodiment of the present disclosure.

FIG. 11 is a block diagram illustrating an embodiment for implementing a controller of FIG. 1.

FIG. 12 is a block diagram illustrating a semiconductor memory device of FIG. 1.

FIG. 13 is a block diagram illustrating an application example of the memory system of FIG. 1.

FIG. 14 is a block diagram illustrating a computing system including the memory system described with reference to FIG. 13.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed therebetween. It will be understood that when an element is referred to as being “between” two elements, it can be the only element between the two elements, or one or more intervening elements may also be present. Like reference numerals refer to like elements throughout. In addition, when an element is referred to as “including” a component, this indicates that the element may further include another component instead of excluding another component unless there is different disclosure.

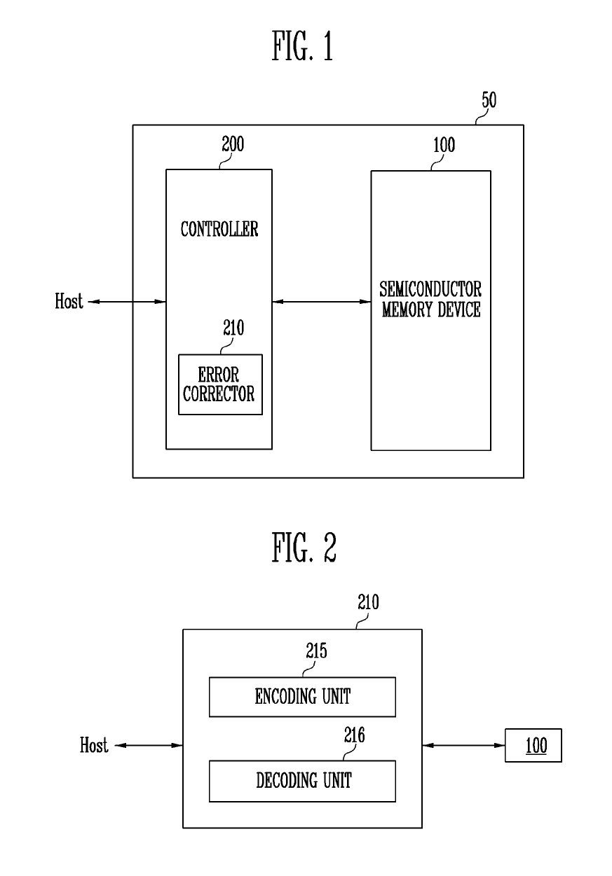

FIG. 1 is a block diagram illustrating a memory system 50 according to an embodiment of the present disclosure.

The memory system 50 is a semiconductor memory device. Referring to FIG. 1, the memory system 50 includes a semiconductor memory device 100 and a controller 200.

The semiconductor memory device 100 operates in response to control signals of the controller 200. The semiconductor memory device 100 includes a plurality of memory cells for storing data. The plurality of memory cells may be nonvolatile memory cells.

The semiconductor memory device 100 performs program, read, and erase operations on the plurality of memory cells in response to the control signal of the controller 200. In an embodiment, the read and program operations of the semiconductor memory device 100 may be performed on a page basis. The erase operation of the semiconductor memory device 100 may be performed on a block basis.

The semiconductor memory device 100 is a nonvolatile memory device. In an embodiment, the semiconductor memory device 100 may be a flash memory device.

The controller 200 controls overall operations of the semiconductor memory device 100. The controller 200 accesses the semiconductor memory device 100 in response to a request from a host Host.

The controller 200 supervises program, read, erase, and background operations of the semiconductor memory device 100. The controller 200 provides an interface between the semiconductor memory device 100 and the host Host. The controller 200 runs firmware for controlling the semiconductor memory device 100.

In an embodiment, the controller 200 performs a function of a flash translation layer (FTL). The controller 200 may manage a map table including a mapping relationship between a logical block address corresponding to the host Host and a physical block address corresponding to the semiconductor memory device 100. The controller 200 may translate a logical block address received from the host Host to a physical block address based on the map table.

When the host Host transmits a read request, the controller 200 may translate a logical block address included in the read request to a physical block address. The controller 200 may provide the semiconductor memory device with a read command and the translated physical block address for the semiconductor memory device 100 to perform a read operation by fetching data from memory cells corresponding to the physical block address. In an embodiment, a plurality of read commands for soft decisions and physical block addresses corresponding thereto may be provided to the semiconductor memory device 100.

In response to the read command, the semiconductor memory device 100 reads data from the memory cells corresponding to the physical block address, and transmits the read data to the controller 200.

The controller 200 includes an error corrector 210. The error corrector 210 corrects errors included in the read data. The error corrector 210 may decode the corresponding data according to an error correction code, and provide the error-corrected data. It will be understood that various methods may be used as the error correction code. For example, it will be understood that error correction codes using various methods including a Bose, Chaudhuri, and Hocquenghem (BCH) code, a Re3d Solomon code, a Reed Muller (RM) code, a Hamming code, a convolution code, a low density parity check (LDPC) code, and the like may be used as the error correction code. The BCH code, the Reed Solomon code, the RM code, and the Hamming code may be applied to hard decision encoding and decoding. Also, the convolution code and the LDPC code may be applied to soft decision encoding and decoding.

If the errors included in the read data are corrected, the controller 200 may output, to the host Host, the error-corrected data.

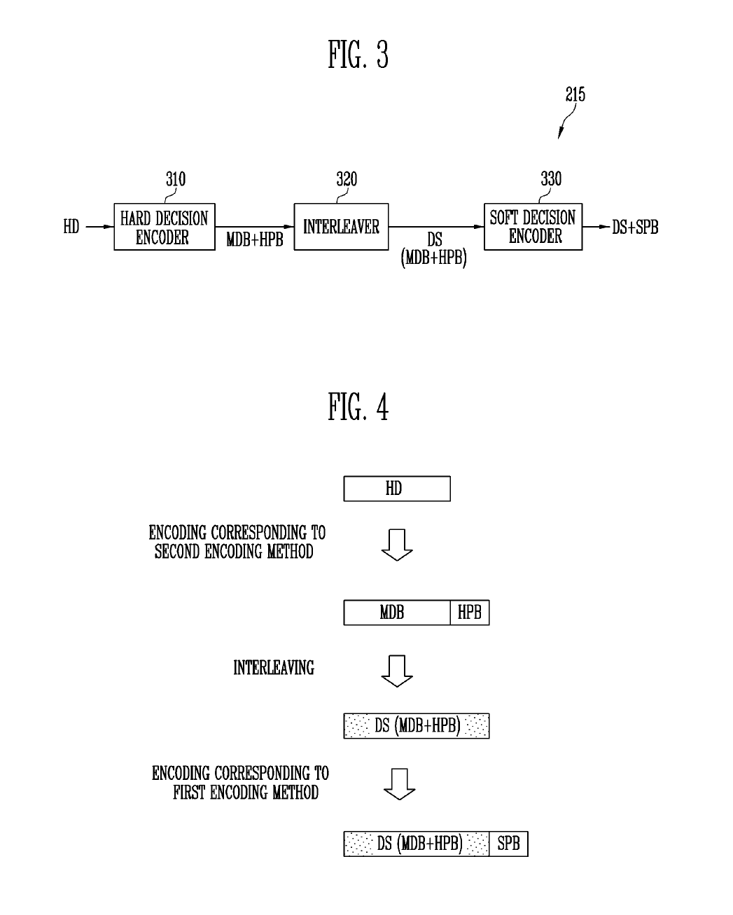

FIG. 2 is a block diagram illustrating the error corrector 210 of FIG. 1.

Referring to FIG. 2, the error corrector 210 includes an encoding unit 215 and a decoding unit 216.

The encoding unit 215 generates parity bits by encoding host data received from the host Host, and adds the generated parity bits to the host data. For example, when a write request is received from the host Host, the encoding of host data may be performed. The processed data is stored in the semiconductor memory device 100.

The decoding unit 216 decodes data read from the semiconductor memory device 100 based on corresponding parity bits, to correct errors in the corresponding data, and provide the error-corrected data. For example, when a write request is received from the host Host, the decoding of data may be performed, and the error-corrected data is output as host data to the host Host.

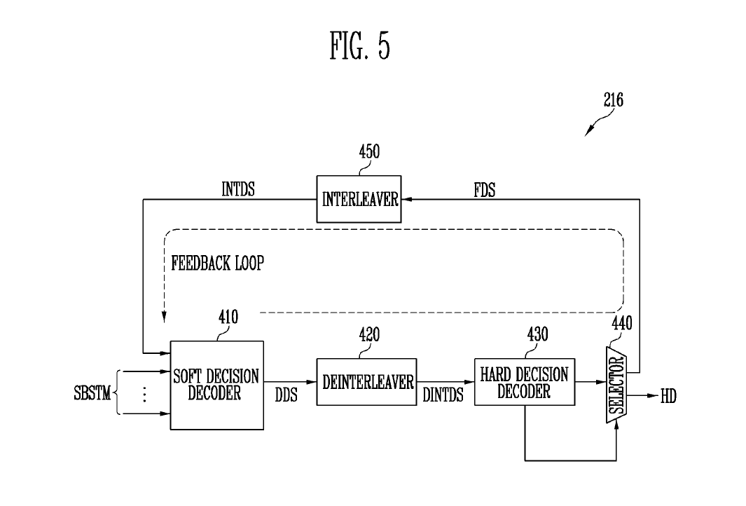

FIG. 3 is a block diagram illustrating the encoding unit 215 of FIG. 2.

Referring to FIG. 3, the encoding unit 215 includes a hard decision encoder 310, an interleaver 320, and a soft decision encoder 330.

The hard decision encoder 310 generates hard decision parity bits HPB by encoding host data HD according to a second encoding method, and output the host data HD and the hard decision parity bits HPB as one bit stream. In this state, the host data HD is output as main data bits MDB.

The second encoding method may be a method using block coding. The second encoding method is efficient in terms of detection and correction of burst errors. In an embodiment, the BCH code, Read Solomon code, RM code, Hamming code, and the like may be used as the second encoding method. When the second encoding method is applied, q-bit source data (i.e., HD) is encoded in blocks of p bits. That is, the source data is divided into p-bit blocks. The hard decision encoder 310 adds r1 hard decision parity bits HPB to the q bits blocked as described above, thereby generating a bit stream MDB+HPB of q+r1 bits. The hard decision parity bits HPB are added to correct errors in the main data bits MDB.

The interleaver 320 outputs one data set DS by interleaving the bit stream MDB+HPB output from the hard decision encoder 310. That is, the interleaver 320 changes the positions of data bits in the bit stream MDB+HPB according to a predetermined method.

It will be understood that, if deinterleaving corresponding to the predetermined method is performed on the data set DS, the bit stream MDB+HPB may be generated.

The soft decision encoder 330 generates soft decision parity bits SPB by encoding the data set DS from the interleaver 320 according to a first encoding method, and outputs the data set DS and the soft decision parity bits SPB.

The first encoding method may be a method of performing coding by using a relationship between data bits of source data (i.e., DS). The first encoding method is efficiency in detection and correction of random errors. In an embodiment, the convolution code, the LDPC code, and the like may be used as the first encoding method.

If the first encoding method is applied, a bit stream DS+SPB of q+r1+r2 bits is generated by encoding source data DS of q+r1 bits. According to the first encoding method, r2 soft decision parity bits SPB are added. The soft decision parity bits SPB are added to correct errors in the source data DS.

The bit stream DS+SPB output from the soft decision encoder 330 may be programmed in selected memory cells of the semiconductor memory device 100.

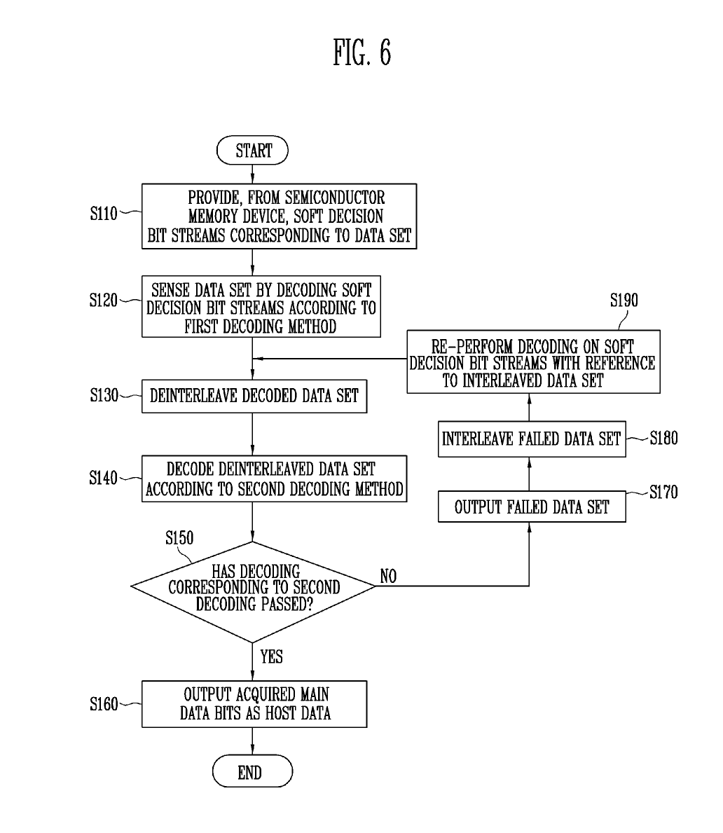

FIG. 4 is a conceptual diagram illustrating a process of encoding host data HD.

Referring to FIG. 4, hard decision parity bits HPB are generated through encoding according to the second encoding method. The host data HD is provided as main data bits MDB.

The main data bits MDB and the hard decision parity bits HPB are interleaved to generate a data set DS. In FIG. 4, interleaved data is identified using dots. Here, it will be understood that the main data bits MDB and the hard decision parity bits HPB may also be included in the data set DS.

Soft decision parity bits SPB are generated through encoding according to the first encoding method. The soft decision parity bits SPB may be added to the data set DS. The data set DS and the soft decision parity bits SPB may be programmed in the semiconductor memory device 100.

FIG. 5 is a block diagram illustrating the decoding unit 216 of FIG. 2.

Referring to FIG. 5, the decoding unit 216 receives, from the semiconductor memory device 100, soft decision bit streams SBSTM corresponding to the data set DS (see FIG. 4) and the soft decision parity bits SPB (see FIG. 4).

The soft decision bit streams SBSTM include information on the data set DS and the soft decision parity bits SPB (see FIG. 4). The soft decision bit streams SBSTM do not determine each data bit included in the data set DS and the soft decision parity bits SPB as “0” or “1” but defines the data bit in a manner such as “very definite 0,” “ definite 0,” “indefinite 0,” “very indefinite 0,” “very indefinite 1,” “indefinite 1,” “definite 1,” or “very definite 1.” For example, three data bits of the soft decision bit streams SBSTM correspond to one data bit of the data set DS and the soft decision parity bits SPB. Therefore, the number of bits included in the soft decision bit streams SBSTM is greater than that of bits included in the data set DS and the soft decision parity bits SPB. For example, the soft decision bit streams SBSTM may have a size that is an integer multiple (e.g., three times) of the data set DS and the soft decision parity bits SPB.

In an embodiment, the controller 200 (see FIG. 1) may provide a plurality of read commands to the semiconductor memory device 100 so as to acquire the soft decision bit streams SBSTM. The semiconductor memory device 100 performs a plurality of read operations on selected memory cells (e.g., memory cells storing DS and SPB) according to the plurality of read commands, thereby providing the soft decision bit streams SBSTM. For example, when the semiconductor memory device 100 outputs page data by performing a read operation on a page basis, the soft decision bit streams SBSTM correspond to a plurality of page data.

The decoding unit 216 includes a soft decision decoder 410, a deinterleaver 420, a hard decision decoder 430, a selector 440, and an interleaver 450.

The soft decision decoder 410 may identify a data set by decoding soft decision bit streams SBSTM according to a first decoding method. The soft decision decoder 410 may identify the data set DS based on information corresponding to soft decision parity bits SPB (see FIG. 4) among the soft decision bit streams SBSTM. The data set DS is output as a decoded data set DDS. For example, if the data set DS is successfully identified, the decoded data set DDS may correspond to the data set DS. If the data set DS is not successfully identified, the decoded data set DDS does not correspond to the data set DS.

Like the data set DS, the decoded data set DDS may have q+r1 bits.

In an embodiment, the convolution code, the LDPC code, and the like may be used as the first decoding method. The first decoding method may correspond to the first encoding method. For example, when encoding according to the convolution code is used as the first encoding method, decoding according to the convolution code may be performed as the first decoding method.

The deinterleaver 420 is configured to output a deinterleaved data set DINTDS by deinterleaving the decoded data set DDS. Error bits randomly arranged in the decoded data set DDS may be deinterleaved to be located as burst errors in the deinterleaved data set DINTDS. A second decoding method used by the hard decision decoder 430 is efficient in terms of correction of burst errors.

The hard decision decoder 430 decodes the deinterleaved data set DINTDS according to the second decoding method based on hard decision parity bits HPB (see FIG. 4) included in the deinterleaved data set DINTDS. If the decoding has been completed successfully, main data bits MDB (see FIG. 4) may be acquired. The hard decision decoder 430 allows the selector 440 to output the main data bits MDB as host data HD. If the decoding has failed, the hard decision decoder 430 allows the selector 440 to output failed data set FDS to the interleaver 450.

In an embodiment, the BCH code, the Reed Solomon code, the RM code, the Hamming code, and the like may be used as the second decoding method. The second decoding method may correspond to the second encoding method. For example, when encoding according to the Reed Solomon code is used as the second encoding method, decoding according to the Reed Solomon code may be performed as the second decoding method. For example, when encoding according to the BCH code is used as the second encoding method, decoding according to the BCH code may be performed as the second decoding method.

The hard decision decoder 430 divides the deinterleaved data set DINTDS into a plurality of data blocks, and decodes the deinterleaved data set DINTDS in data blocks. For example, when the deinterleaved data set DINTDS is divided into eight data blocks, the hard decision decoder 430 may decode each data block based on corresponding hard decision parity bits.

Accordingly, it is determined whether the decoding has been completed successfully for each data block. If the decoding of all the data blocks has been completed successfully, the decoding of the deinterleaved data set DINTDS may be completed successfully. If the decoding of at least one data block has failed, the decoding of the deinterleaved data set DINTDS fails.

The failed data set FDS is provided as a single hard decision bit stream. The failed data set FDS may have the same data size as the deinterleaved data set DINTDS. The failed data set FDS includes a data block of which decoding has been completed successfully and a data block of which decoding has failed. In this case, the data block of which decoding has been completed successfully may also include corresponding hard decision parity bits as well as the data block of which decoding has failed.

The interleaver 450 generates an interleaved data set INTDS by interleaving the failed data set FDS. The interleaved data set INTDS is fed back to the soft decision decoder 410. The interleaver 450 may perform interleaving by using the same method as the interleaver 320 described with reference to FIG. 3. Error bits located as burst errors in the failed data set FDS may be interleaved to be located as random errors in the interleaved data set INTDS. The first decoding method used by the soft decision decoder 410 is efficient in correction of random errors.

In an embodiment, like the data set DS (see FIG. 4), each of the decoded data set DDS, the deinterleaved data set DINTDS, the failed data set FDS, and the interleaved data set INTDS may have q+r1 bits.

The soft decision decoder 410 may re-perform decoding according to the first decoding method on the soft decision bit streams SBSTM based on the interleaved data set INTDS.

According to an embodiment of the present disclosure, the soft decision decoder 410, the deinterleaver 420, the hard decision decoder 430, the selector 440, and the interleaver 450 constitute a feedback loop. The deinterleaver 420 is located at a front end of the hard decision decoder 430, and the data set DINTDS deinterleaved by the deinterleaved 420 has burst errors. The hard decision decoder 430 efficiently corrects the burst errors. The interleaver 450 is located at a front end of the soft decision decoder 410, and the data set INTDS interleaved by the interleaver 450 has random errors. The soft decision decoder 410 efficiently corrects the random errors. Thus, the error correction performance of the decoding unit 216 may be improved.

According to the embodiment of the present disclosure, the hard decision decoder 430 provides failed data set FDS according to a single hard decision bit stream, and the failed data set FDS is interleaved to be fed back to the soft decision decoder 410.

It is assumed that another plurality of soft decision bit streams is input as a feedback of the soft decision decoder 410. The input of the soft decision decoder 410 may be the initial soft decision bit streams SBSTM and the plurality of soft decision bit streams. The soft decision decoder 410 is to perform decoding with both the initial soft decision bit streams SBSTM and the plurality of soft decision bit streams. As a relatively large quantity of feedback data is added, the load of the soft decision decoder 410 is considerably increased.

A single hard decision bit stream may be provided as a feedback of the soft decision decoder 410. The single hard decision bit stream may be added as an input of the soft decision decoder 410 to the initial soft decision bit streams SBSTM. In this case, even if the soft decision decoder 410 is included in the feedback loop, the load of the soft decision decoder 410 is not considerably increased. Thus, the power consumption, area consumption, and operation time of the soft decision decoder 410 are saved.

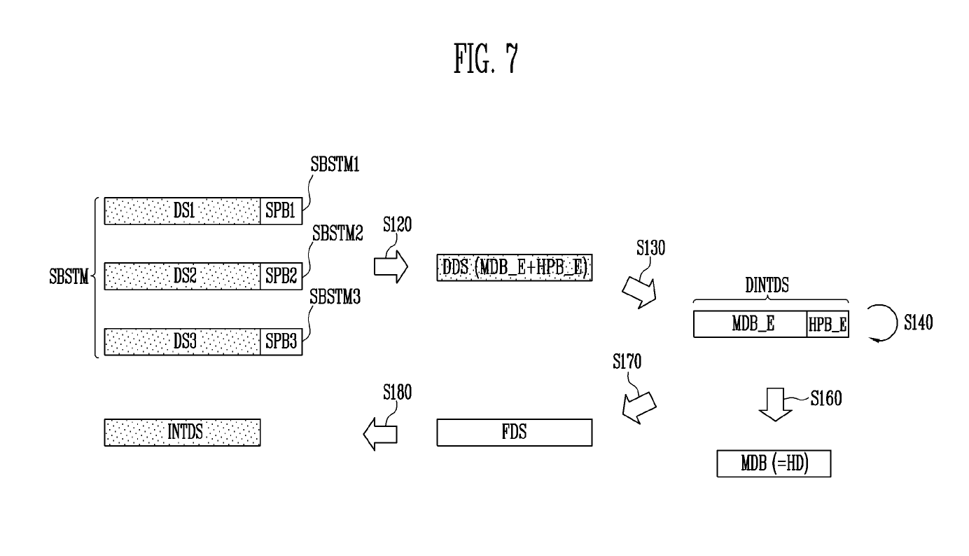

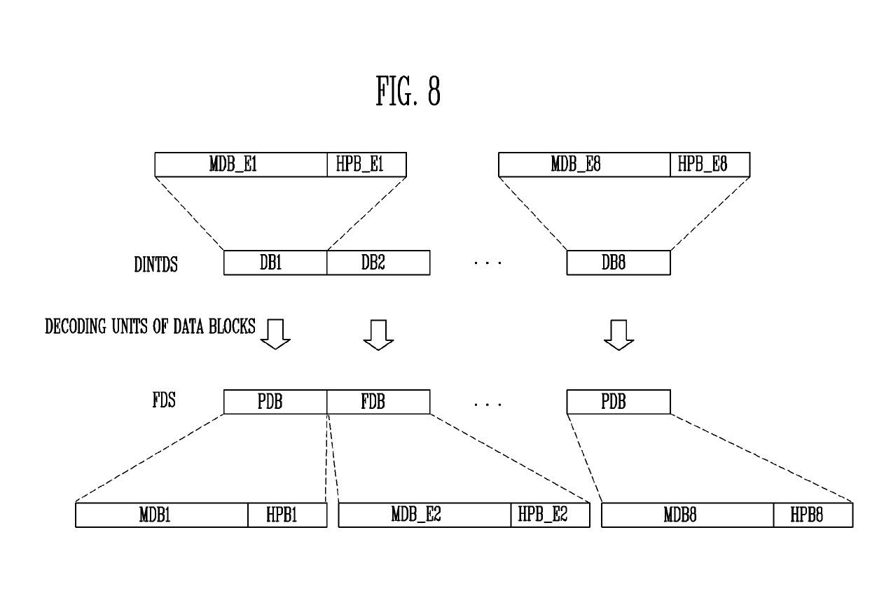

FIG. 6 is a flowchart illustrating a decoding method according to an embodiment of the present disclosure. FIG. 7 is a diagram conceptually illustrating data processed according to the decoding method.

The decoding method of FIG. 6 will be described with reference to FIGS. 1 and 7. In step S110, soft decision bit streams SBSTM corresponding to a data set DS (see FIG. 4) are provided from the semiconductor memory device 100. The soft decision bit streams SBSTM may include information corresponding to the data set DS (see FIG. 4) and soft decision parity bits SPB (see FIG. 4). For example, the data set DA and the soft decision parity bits SPB may be read as soft decision bit streams SBSTM by performing a plurality of read operations.

In FIG. 7, for example, it is illustrated that three soft decision bit streams SBSTM1 to SBSTM3 are provided. A first soft decision bit stream SBSTM1 may be read in a first read operation. The first soft decision bit stream SBSTM1 includes a first data set DS1 and first soft decision parity bits SPB1. A second soft decision bit stream SBSTM2 may be read in a second read operation. The second soft decision bit stream SBSTM2 includes a second data set DS2 and second soft decision parity bits SPB2. A third soft decision bit stream SBSTM3 may be read in a third read operation. The third soft decision bit stream SBSTM3 includes a third data set DS3 and third soft decision parity bits SPB3.

In step S120, the soft decision bit streams SBSTM are decoded according to a first decoding method to identify a data set DS.

In FIG. 7, a data set DS is identified based on the first to third soft decision parity bits SPB1 to SPB3, and the data set DS is output as a decoded data set DDS. If errors are included in the decoded data set DDS, the decoded data set DDS includes main data bits MDB_E including errors and hard decision parity bits HPB_E including errors.

In step S130, the decoded data set DDS is interleaved.

In FIG. 7, through the interleaving, the main data bits MDB_E including errors and the hard decision parity bits HPB_E including errors are aligned in a deinterleaved data set DINTDS. In an embodiment, the main data bits MDB_E including errors and the hard decision parity bits HPB_E including errors may be aligned in units of data blocks.

In step S140, the deinterleaved data set DINTDS is decoded according to a second decoding method. In an embodiment, the deinterleaved data set DINTDS may be decoded in data blocks.

In step S150, step S160 or step S170 is performed according to whether the decoding according to the second decoding method has been completed successfully. If the decoding of all data blocks has been completed successfully, the decoding of the deinterleaved data set DINTDS may be completed successfully. If the decoding of at least one data block has failed, the decoding of the deinterleaved data set DINTDS fails.

In step S160, main data bits MDB are acquired. In FIG. 7, the main data bits MDB are output as host data HD.

In step S170, a failed data set FDS is output. Each data block of the failed data set FDS is a data block of which decoding has been completed successfully or a data block of which decoding has failed.

In step S180, the failed data set FDS is interleaved.

In FIG. 7, the failed data set FDS is translated to an interleaved data set INTDS. Each of the decoded data set DDS, the deinterleaved data set DINTDS, the failed data set FDS, and the interleaved data set INTDS may have the same data size as the data set DS.

In step S190, decoding according to the first decoding method is re-performed on the soft decision bit streams SBSTM based on the interleave data set INTDS.

In FIG. 7, if an x^{th} data bit of the interleaved data set INTDS corresponds to a data block of which decoding has been completed successfully, an x^{th} data bit of the decoded data set DDS may be determined. For example, if the x^{th} data bit of the interleaved data set INTDS is “0,” the x^{th} data bit of the decoded data set DDS may be determined as “0” regardless of an x^{th} data bit of each of the first to third soft decision bit streams SBSTM1 to SBSTM3. Also, if the x^{th} data bit of the interleaved data set INTDS is “1,” the x^{th} data bit of the decoded data set DDS may be determined as “1” regardless of the x^{th} data bit of each of the first to third soft decision bit streams SBSTM1 to SBSTM3. If a y^{th} data bit of the interleaved data set INTDS corresponds to a data block of which decoding fails, the decoding according to the first decoding method may be performed on the first to third soft decision bit streams SBSTM1 to SBSTM3, so that a y^{th} data bit of the decoded data set DDS is determined.

Steps S130 to S150 and steps S170 to S190 are repeated until the decoding according to the second decoding method has been completed successfully.

FIG. 8 is a conceptual diagram illustrating a deinterleaved data set DINTDS and a failed data set FDS.

Referring to FIG. 8, the deinterleaved data set DINTDS is aligned in unit of data blocks. The deinterleaved data set DINTDS includes first to eighth data blocks DB1 to DB8 which are sequentially aligned.

One data block includes main data bits including errors and hard decision parity bits including errors. For example, the first data block DB1 includes main data bits MDB_E1 including errors and hard decision parity bits HPB_E1 including errors. The eighth data block DB8 includes main data bits MDB_E8 including errors and hard decision parity bits HPB_E8 including errors. The main data bits MDB_E1 to MDB_E8 including errors may constitute the main data bits MDB_E including errors in FIG. 7. The hard decision parity bits HPB_E1 to HPB_E8 including errors may constitute the hard decision parity bits HPB_E including errors in FIG. 7.

The decoding according to the second decoding method is performed on a data block basis. The decoding according to the second decoding method may be performed on each of the first to eighth data blocks DB1 to DB8. When the decoding of each data block (e.g., DB1) is performed, the errors included in main data bits (e.g., MDB_E1) are corrected based on hard decision parity bits (e.g., HPB_E1) including errors.

It is assumed that the decoding has been performed on the first to eighth data blocks DB1 to DB8 and the decoding of the second data block DB2 has failed. The failed data set FDS includes a passed data block PDB of which decoding has been completed successfully and a failed data block FDB of which decoding has failed. The passed data block may include error-corrected main data bits and error-corrected hard decision parity. The passed data block PDB corresponding to the first data block DB1 includes corrected main data bits MDB1 and corrected hard decision parity bits HPB1. It will be understood that the corrected main data bits MDB1 may be acquired by correcting the errors included in the main data bits MDB_E1. It will also be understood that the corrected hard decision parity bits HPB1 may be acquired by correcting the errors included in the hard decision parity bits HPB_E1. The passed data block PBD corresponding to the eighth data block DB8 includes corrected main data bits MDB8 and corrected hard decision parity bits HPB8.

The failed data block may include main data bits including errors and hard decision parity bits including errors. Like the second data block DB2, the failed data block FBD corresponding to the second data block DB2 includes main data bits MDB_E2 including errors and hard decision parity bits HPB_E2 including errors.

According to this method, the failed data block FBD has the same size as a corresponding data block, and the passed data block PDB also has the same size as the corresponding data block. The failed data set FDS may have the same data size as the deinterleaved data set DINTDS.

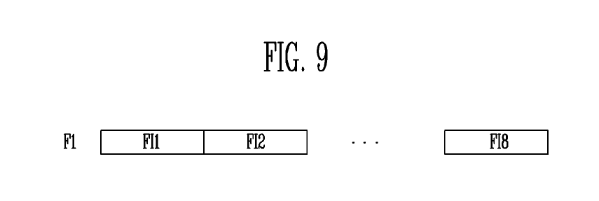

FIG. 9 is a conceptual diagram illustrating flag information FI.

The hard decision decoder 430 (see FIG. 5) may further generate flag information FI. Referring to FIG. 9, the flag information FI includes first to eighth flag information FI1 to FI8. The first to eighth flag information FI1 to FI8 correspond to first to eights data blocks DB1 to DB8, respectively. Each of the first to eighth flag information represents whether the decoding of a corresponding data block has been completed successfully or failed. A piece of flag information may include data bits respectively corresponding to those of a corresponding data block. That is, the piece of flag information may have the same data size as the corresponding data block. For example, logical values of data bits included in each piece of flag information may be “1” or “0.”

The flag information FI may be provided to the soft decision decoder 410 (see FIG. 5). The soft decision decoder 410 may perform decoding on soft decision bit streams SBSTM based on the flag information FI and an interleaved data set INTDS. For example, the soft decision decoder 410 may determine, based on the flag information FI, whether the x^{th} data bit of the interleaved data set INTDS corresponds to a data block of which decoding has been completed successfully. The soft decision decoder 410 may determine, based on the flag information FI, whether the y^{th} data bit of the interleaved data set INTDS corresponding to a data block of which decoding has failed.

In an embodiment, the flag information FI is added to a failed data set FDS, and the interleaver 450 (see FIG. 5) simultaneously interleaves the failed data set FDS and the flag information FI. The interleaved data may be fed back to the soft decision decoder 410.

In an embodiment, the flag information FI may be provided to the soft decision decoder 410 without passing through the interleaver 450.

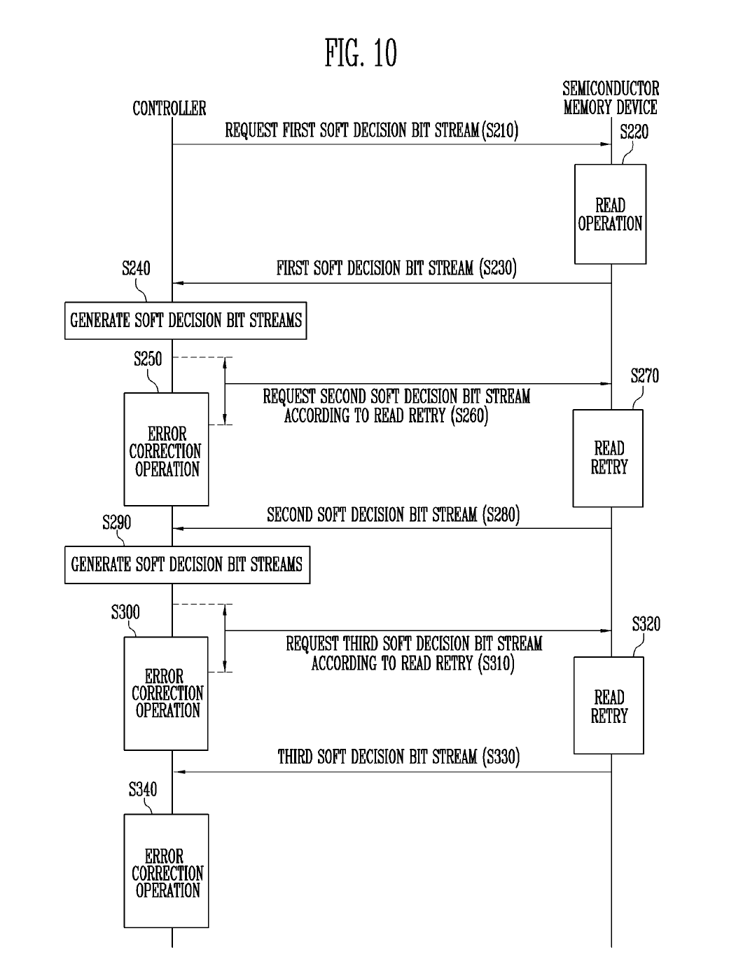

FIG. 10 is a flowcharting illustrating a method of operating the memory system 50 according to an embodiment of the present disclosure.

Referring to FIGS. 1 and 10, in step S210, the controller 200 requests the semiconductor device 100 of a first soft decision bit stream. In step S220, the semiconductor memory device 100 performs a read operation. In step S230, the semiconductor memory device 100 transmits, to the controller 200, the first soft decision bit stream read by the read operation.

In step S240, the controller 200 may generate a plurality of soft decision bit streams based on the first soft decision bit stream. The plurality of soft decision bit streams may correspond to soft decision bit streams SBSTM1 to SBSTM3 described with reference to FIG. 7. The controller 200 may generate three data bits according to each data bit of the first soft decision bit stream, thereby generating the soft decision bit streams SBSTM1 to SBSTM3. For example, if a z^{th} data bit of the first soft decision bit stream is “1,” z^{th} data bits of the soft decision bit streams SBSTM1 to SBSTM3 may be “very definite 1.” Also, if the z^{th} data bit of the first soft decision bit stream is “0,” the z^{th} data bits of the soft decision bit streams SBSTM1 to SBSTM3 may be “very definite 0.” In addition, it will be understood that one bit stream may be translated to three bit streams by using various methods.

In step S250, the controller 200 performs an error correction operation. The error correction operation may include steps S120 to S190 of FIG. 6.

In step S260, the controller 200 requests a second soft decision bit stream according to a read-retry operation before the error correction operation or during the error correction operation. For example, the controller 200 may control the semiconductor memory device 100 to adjust a read voltage applied to a word line connected to selected memory cells and perform the read operation by using the adjusted read voltage.

In step S270, the semiconductor memory device 100 performs the read-retry operation. According to the embodiment of the present disclosure, the error correction operation (S250) performed by the controller 200 and the read-retry operation (S270) performed by the semiconductor memory device 100 are performed in parallel. For example, the read-retry operation (S270) performed by the semiconductor memory device 100 is performed in parallel to any one of steps S120 to S190 of FIG. 6.

In step S280, the semiconductor memory device 100 outputs the second soft decision bit stream as a result of the read-retry operation (S260).

In step S290, the controller 200 regenerates a plurality of soft decision bit streams based on the first and second soft decision bit streams obtained in steps S230 and S280. The plurality of soft decision bit streams may correspond to the soft decision bit streams SBSTM1 to SBSTM3 of FIG. 7. Since the regeneration of the soft decision bit streams is performed based on two soft decision bit streams, it can be expected that the regenerated soft decision bit streams will have higher reliability. The controller 200 may generate three data bits according to two z^{th} data bits of the first and second soft decision bit streams, thereby generating the soft decision bit streams SBSTM1 to SBSTM3. For example, if the logical values of the z^{th} data bits of the first and second soft decision bit streams are “1” and “1,” respectively, the z^{th} data bits of the soft decision bit streams SBSTM1 to SBSTM3 may be “very definite 1.” Also, if the logical values of the z^{th} data bits of the first and second soft decision bit streams are “1” and “0,” respectively, the z^{th} data bits of the soft decision bit streams SBSTM1 to SBSTM3 may be any one of “indefinite 0,” “very indefinite 0,” “very indefinite 1,” and “indefinite 1.” Also, if the logical values of the z^{th} data bits of the first and second soft decision bit streams are “0” and “0,” respectively, the z^{th} data bits of the soft decision bit streams SBSTM1 to SBSTM3 may be “very definite 0.”

In step S300, the controller 200 re-performs the error correction operation. If the decoding according to the second decoding method in step S250 fails (S150, see FIG. 6), the soft decision bit streams SBSTM1 to SBSTM3 regenerated in step S290 may be provided as an input of the decoding according to the first decoding method. As the soft decision bit streams SBSTM1 to SBSTM3 regenerated in step S290 are input, the number of error bits included in output data DDS of the soft decision decoder 410 can be decreased.

If the decoding according to the second decoding method in step S250 has been completed successfully (S150), step S300 may not be performed. In an embodiment, the controller 200 may discard the second soft decision bit stream received from the semiconductor memory device 100 or the plurality of soft decision bit streams regenerated in step S290.

In step S310, the controller 200 requests a third decision bit stream according to the read-retry operation before the error correction operation in step S300 or during the error correction operation in step S300.

In step S320, the semiconductor memory device 100 performs the read-retry operation. The semiconductor memory device 100 may re-adjust a read voltage applied to a word line connected to selected memory cells, and perform the read operation by using the corresponding read voltage. The error correction operation in step S300 and the read-retry operation in step S320 are performed in parallel.

In step S330, the semiconductor memory device 100 outputs the third soft decision bit stream as a result of the read-retry operation (S320).

In step S340, the controller 200 re-performs the error correction operation. If the decoding according to the second decoding method in step S300 has failed (S150, see FIG. 6), the first to third soft decision bit streams obtain in steps S230, S280, and S330 may be provided as an input of the decoding according to the first decoding method. The first to third soft decision bit streams may correspond to the soft decision bit streams SBSTM1 to SBSTM3 of FIG. 7. The soft decision bit streams SBSTM1 to SBSTM3 can be expected to have higher reliability than the soft decision bit streams generated in steps S240 and S290.

According to an embodiment of the present disclosure, the error correction operation of the controller 200 and the read-retry operation of the semiconductor memory device 100 are performed in parallel. Thus, it is possible to improve the operation speed of the memory system 50 while providing a read-retry function.

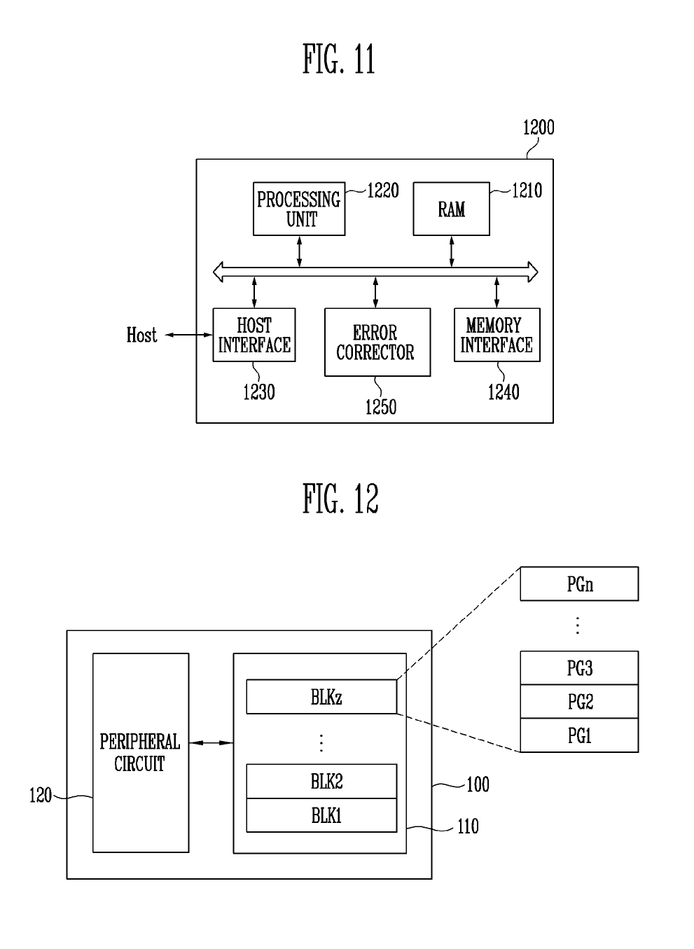

FIG. 11 is a block diagram illustrating an embodiment 1200 for implementing the controller 200 of FIG. 1.

Referring to FIG. 11, the controller 1200 includes a random access memory (RAM) 1210, a processing unit 1220, a host interface 1230, a memory interface 1240, and an error corrector 1250.

The processing unit 1220 controls overall operations of the controller 1200. The RAM 1210 may be used as at least one of an operation memory of the processing unit 1220, a cache memory between the semiconductor memory device 100 (see FIG. 1) and the host Host (see FIG. 1), and a buffer memory between the semiconductor memory device 100 and the host Host. The processing unit 1220 and the RAM 1210 control overall operations of the controller 1200. For example, the processing unit 1220 may load program commands, data files, data structures, and the like from the RAM 1210, and execute the loaded data, thereby performing the overall operations of the controller 1200.

The host interface 1230 includes a protocol for exchanging data between the host Host and the controller 1200. In an embodiment, the controller 1200 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1240 interfaces with the semiconductor memory device 100. The error corrector 1250 performs functions of the error corrector 210 of FIG. 1.

The controller 1200 and the semiconductor memory device 100 may be integrated into one semiconductor device. In an embodiment, the controller 1200 and the semiconductor memory device 100 may be integrated into one semiconductor device to constitute a memory card. For example, the controller 1200 and the semiconductor memory device 100 may be integrated into one semiconductor device to constitute a memory card such as a PC card such as personal computer memory card international association (PCMCIA), a compact flash (CF) card, a smart media card (SM or SMC), a memory stick, a multimedia card (e.g., MMC, RS-MMC, or MMCmicro), an SD card (e.g., SD, miniSD, microSD, or SDHC), or a universal flash storage (UFS).

The controller 1200 and the semiconductor memory device 100 may be integrated into one semiconductor device to constitute a semiconductor drive such as a solid state drive (SSD). If the controller 1200 and the semiconductor memory device 100 are used as the semiconductor drive SSD, the operating speed of the host can be remarkably improved.

In an example, the controller 1200 and the semiconductor memory device 100 may be provided as one of various components of an electronic device such as a computer, a ultra mobile PC (UMPC), a workstation, a net-book, a personal digital assistant (PDA), a portable computer, a web tablet, a wireless phone, a mobile phone, a smart phone, an e-book, a portable multimedia player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telemetics network, an RFID device, or one of various components that constitute a computing system.

In an embodiment, the controller 1200 and the semiconductor memory device 100 may be packaged in various forms. For example, the semiconductor memory device 100 or the memory system 1000 may be packaged in a manner such as package on package (PoP), ball grid arrays (BGAs), chip scale packages (CSPs), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), thin quad flat pack (TQFP), system in package (SIP), multi chip package (MCP), wafer-level fabricated package (WFP), or wafer-level processed stack package (WSP).

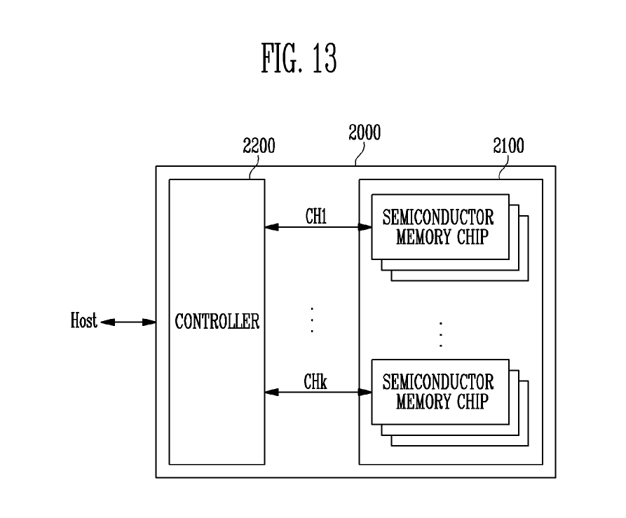

FIG. 12 is a block diagram illustrating the semiconductor memory device 100 of FIG. 1.

Referring to FIG. 12, the semiconductor memory device 100 includes a memory cell array 110 and a peripheral circuit for driving the memory cell array 110. The memory cell array 110 includes a plurality of memory blocks BLK1 to BLKz. Each of the plurality of memory blocks BLK1 to BLKz includes a plurality of pages PG1 to PGn. It will be understood that each page may include memory cells connected to a word line.

The peripheral circuit 120 operates in response to control of the controller 200.

When a program operation is performed, the peripheral circuit 120 may receive, from the controller 200, a program command, a physical block address, and data. A memory block and a page included therein may be selected by the physical block address. The peripheral circuit 120 may program data in the selected page.

When a read operation is performed, the peripheral circuit 120 may receive, from the controller 200, a read command and a physical block address. A memory block and a page included therein may be selected by the physical block address. The peripheral circuit 120 may read data from the selected page, and output the read data to the controller 200.

When an erase operation is performed, the peripheral circuit 120 may receive, from the controller 200, an erase command and a physical block address. A memory block may be selected by the physical block address. The peripheral circuit 120 may erase data of the memory block corresponding to the physical block address.

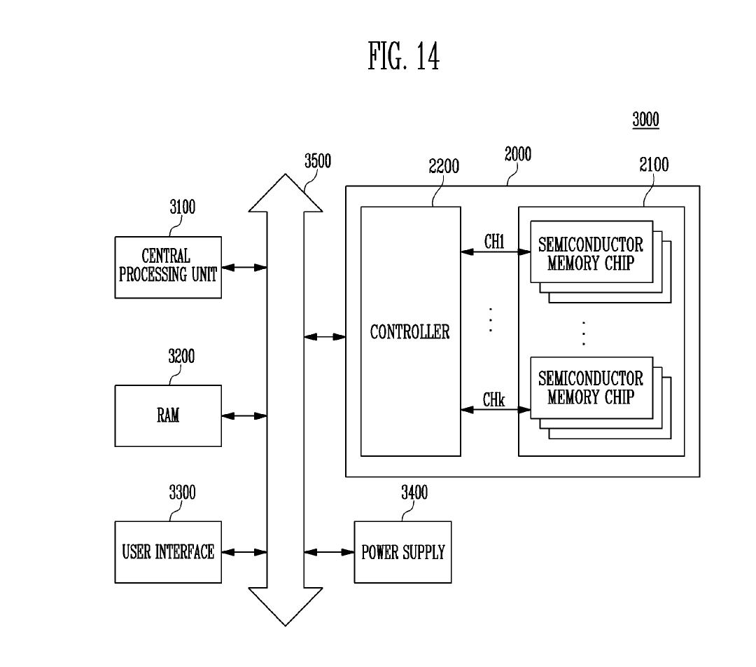

FIG. 13 is a block diagram illustrating an application example 2000 of the memory system 50 of FIG. 1.

Referring to FIG. 13, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 13, it has been illustrated that the plurality of groups communicates with the controller 2200 through first to k^{th} channels CH1 to CHk. Each semiconductor memory chip may be configured and operate like any one of the semiconductor memory devices 100 described with reference to FIG. 12.

Each group may communicate with the controller 2200 through one common channel. The controller 2200 is configured like the controller 200 described with reference to FIG. 1. The controller 2200 may control the plurality of memory chips of the semiconductor memory device 2100 through the plurality of channels CH1 to CHk.

In FIG. 13, it has been illustrated that a plurality of semiconductor memory chips are coupled to one channel. However, it will be understood that the memory system 2000 may be modified such that one semiconductor memory chip is connected to one channel.

FIG. 14 is a block diagram illustrating a computing system 3000 including the memory system 2000 described with reference to FIG. 13.

Referring to FIG. 14, the computing system 3000 includes a central processing unit 3100, a random access memory (RAM) 3200, a user interface 3300, a power source 3400, a system bus 3500, and the memory system 2000.

The memory system 2000 is electrically connected to the central processing unit 3100, the RAM 3200, the user interface 3300, and the power source 3400 through the system bus 3500. Data supplied through user interface 3300 or data processed by the central processing unit 3100 are stored in the memory system 2000.

In FIG. 14, it is illustrated that the semiconductor memory device 2100 is coupled to the system bus 3500 through the controller 2200. However, the semiconductor memory device 2100 may be directly connected to the system bus 3500. In this case, the function of the controller 2200 may be performed by the central processing unit 3100 and the RAM 3200.

In FIG. 14, it is illustrated that the memory system 2000 described with reference to FIG. 13 is provided. However, the memory system 2000 may be replaced by the memory system 50 described with reference to FIG. 1. In an embodiment, the computing system 3000 may be configured to include both the memory systems 50 and 2000 described with reference to FIGS. 1 and 13.

According to various embodiments of the present disclosure, the soft decision decoder, the deinterleaver, the hard decision decoder, the selector, and the interleaver constitute a feedback loop. Thus, the error correction performance of the decoding unit is improved.

According to various embodiments of the present disclosure, the hard decision decoder provides a failed data set corresponding to a single hard decision bit stream, and the failed data set is interleaved to be fed back to the soft decision decoder. Thus, a low-power-consumption, miniaturized, high-speed soft decision decoder can be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory system comprising:
a controller; and
a semiconductor memory device configured to store a data set having main data bits and parity bits and provide soft decision bit streams corresponding to the data set in response to control signals of the controller,
wherein the controller includes:
a soft decision decoder configured to identify the data set by decoding the soft decision bit streams according to a first decoding method;
a deinterleaver configured to deinterleave the identified data set;
a hard decision decoder configured to decode the deinterleaved data set according to a second decoding method based on the parity bits included in the deinterleaved data set, and output a failed data set if the decoding according to the second decoding method has failed; and
an interleaver configured to interleave the failed data set,
wherein the interleaved data set is fed back to the soft decision decoder.

2. The memory system of claim 1, wherein the soft decision decoder re-decodes the soft decision bit streams based on the interleaved data set.

3. The memory system of claim 1, wherein the soft decision decoder, the deinterleaver, the hard decision decoder, and the interleaver are included in one feedback loop.

4. The memory system of claim 1, wherein the failed data set has the same size as the data set.

5. The memory system of claim 1, wherein the main data bits are acquired if the decoding according to the second decoding method has been completed successfully, and
wherein the hard decision decoder outputs the main data bits as host data.

6. The memory system of claim 1, wherein the deinterleaved data set is divided into a plurality of data blocks,
wherein the decoding according to the second decoding method is performed on the data block basis, and
wherein the failed data set includes a data block of which the decoding according to the second decoding method has failed and a data block of which the decoding according to the second decoding method has been completed successfully.

7. The memory system of claim 6, wherein the hard decision decoder further outputs a plurality of flag information respectively corresponding to the plurality of data blocks, and
wherein each of the plurality of flag information represents whether the decoding according to the second decoding method has been completed successfully or failed with respect to a corresponding data block.

8. The memory system of claim 7, wherein the soft decision decoder re-decodes the soft decision bit streams based on the plurality of flag information and the interleaved data set.

9. The memory system of claim 1, wherein the semiconductor memory device performs a read-retry operation in response to control signals of the controller and outputs, to the controller, second soft decision bit streams corresponding to the data set, and
wherein the read-retry operation is performed in parallel to at least one of the decoding according to the first decoding method, the deinterleaving, the decoding according to the second decoding method, and the interleaving.

10. The memory system of claim 9, wherein the soft decision decoder decodes the second soft decision bit streams according to the first decoding method based on the interleaved data set.

11. The memory system of claim 1, wherein the first decoding method corresponds to a convolution code.

12. The memory system of claim 1, wherein the first decoding method corresponds to a low density parity check (LDPC) code.

13. The memory system of claim 1, wherein the second decoding method corresponds to a Reed Solomon code.

14. The memory system of claim 1, wherein the second decoding method corresponds to a Bose, Chaudhuri, and Hocquenghem (BCH) code.

15. The memory system of claim 1, wherein the controller includes:
a hard decision encoder configured to generate the parity bits by encoding host data according to a second encoding method corresponding to the second decoding method; and
a second interleaver configured to generate the data set by interleaving the host data and the parity bits,
wherein the data set is encoded according to a first encoding method corresponding to the first decoding method to be stored in the semiconductor memory device.

16. A method of operating a semiconductor system, the method comprising:
providing soft decision bit streams corresponding to a data set, the data set having main data bits and parity bits;
identifying the data set by decoding the soft decision bit streams according to a first decoding method;
deinterleaving the identified data set;
decoding the deinterleaved data set according to a second decoding method based on the parity bits of the deinterleaved data set;
outputting a failed data set if the decoding according to the second decoding method has failed;
interleaving the failed data set; and
re-performing the decoding according to the first decoding method based on the deinterleaved data set.

17. The method of claim 16, wherein deinterleaving the identified data set, decoding the deinterleaved data set according to the second decoding method, outputting the failed data set, interleaving the failed data set, and re-performing the decoding according to the first decoding method are repeated until the decoding according to the second decoding method is completed successfully.

18. The method of claim 16, wherein the failed data set has the same size as the data set.

19. The method of claim 16, further comprising providing second soft decision bit streams corresponding to the data set,
wherein providing the second soft decision bit streams is performed in parallel to at least one of decoding according to the first decoding method, deinterleaving the identified data set, decoding according to the second decoding method, outputting the failed data set, and interleaving the failed data set.

20. The method of claim 19, wherein re-performing the decoding according to the first decoding method includes decoding the second soft decision bit streams according to the first decoding method based on the interleaved data set.
